(19) United States
(12) Patent Application Publication
(10) Pub. No.: US 2026/0112581 A1
(43) Pub. Date: Apr. 23, 2026

(54) STRUCTURAL MEMBER

(71) Applicant: TOTO LTD., Fukuoka (JP)

(72) Inventors: Shun KATAOKA, Fukuoka (JP); Senri SAKAMOTO, Fukuoka (JP); Ryoto TAKIZAWA, Fukuoka (JP)

(73) Assignee: TOTO LTD., Fukuoka (JP)

(21) Appl. No.: 19/312,869

(22) Filed: Aug. 28, 2025

(30) Foreign Application Priority Data
Oct. 18, 2024 (JP) 2024-184122
Jan. 27, 2025 (JP) 2025-011537

(51) Int. Cl. H01J 37/32

(52) U.S. Cl. CPC H01J 37/32495; H01J 37/32467; H01J 2237/0213

(57) ABSTRACT

A structural member 10 includes a substrate 100 and a passivation film 200 covering the surface of the substrate 100. The passivation film 200 includes lanthanum zirconium oxide as a main component and has an indentation hardness of more than 7.2 GPa.

### CROSS-REFERENCE TO RELATED APPLICATION

This application is based upon and claims the benefit of priority from Japanese Patent Application Nos. 2024-184122, filed on Oct. 18, 2024, and 2025-011537, filed on Jan. 27, 2025, the entire contents of which are incorporated herein by reference.

### FIELD

The present invention relates to a structural member.

### BACKGROUND

Resistance (Durability) against plasma is required for members constituting a semiconductor manufacturing apparatus, for example, members such as chamber inner walls and the like. Therefore, structural members having a passivation film (protective film) formed on the surface of a substrate (base material) have been commonly used as the above members as disclosed in Japanese Translation of PCT International Application Publication No. 2019-507962. Oxide ceramics, such as yttria, are often used as passivation films.

### SUMMARY

The present inventors have been considering the use of lanthanum zirconium oxide as a material for passivation films and further improvement in the resistance of passivation film against plasma.

The present invention has been made in view of such problems and an object of the present invention is to provide a structural member having sufficient resistance against plasma.

To solve the above problem, the structural member of the present invention comprises a substrate and a passivation film covering the surface of the substrate. The passivation film comprises lanthanum zirconium oxide as a main component, and has an indentation hardness of more than 7.2 GPa.

The experiments conducted by the present inventors have demonstrated that there is a correlation between the indentation hardness of passivation film comprising lanthanum zirconium oxide as a main component and the resistance of the passivation film against plasma. It has also been confirmed that when the passivation film is configured to have an indentation hardness of more than 7.2 GPa, the resistance of the passivation film against plasma can be sufficiently improved.

According to the present invention, a structural member with sufficient resistance against plasma can be provided.

### BRIEF DESCRIPTION OF THE DRAWINGS

FIG. 1 schematically illustrates a cross-section of the structural member;

FIG. 2 is a graph illustrating the relationship between the indentation hardness of the passivation film and the resistance of the passivation film against plasma;

FIG. 3 is a graph illustrating the relationship between the indentation hardness of the passivation film and the resistance of the passivation film against plasma;

FIG. 4 is a table listing film-forming conditions and the like when forming a passivation film;

FIG. 5 shows micrographs illustrating the surface shape of the passivation film;

FIGS. 6A to 6C show micrographs illustrating the porosity of the passivation film;

FIG. 7 is a table listing film-forming conditions and the like when forming a passivation film; and

FIG. 8 is a graph showing the change in surface roughness of the passivation film over time when the passivation film is immersed in hydrochloric acid.

### DETAILED DESCRIPTION

Hereinafter the present embodiment will be described with reference to attached drawings. For clarity of description, identical reference numerals are used to denote the same elements in all figures, and redundant descriptions are omitted.

The structural member 10 of the present embodiment is configured as a member for a semiconductor manufacturing apparatus, such as a plasma etching apparatus. More specifically, the structural member 10 is a member used for the inner wall of a process chamber of semiconductor manufacturing apparatus. The use of the structural member 10 in the present embodiment is merely an example. The structural member 10 may be a member arranged within the process chamber of semiconductor manufacturing apparatus, such as a focus ring.

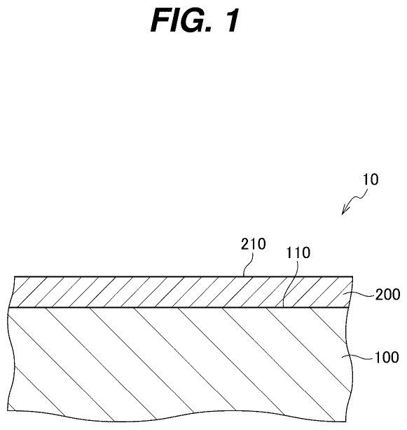

As shown in FIG. 1, the structural member 10 includes a substrate 100 and a passivation film 200. In a plasma etching apparatus or the like, the surface 210 of the passivation film 200 is exposed to the interior of the process chamber. The passivation film 200 is formed to protect the surface 110 of the substrate 100 from plasma.

The substrate 100 is a member forming the primary portion of the structural member 10. In the present embodiment, the substrate 100 is a sintered ceramic body including high-purity aluminum oxide (Al₂O₃), but may be a different ceramic material or member other than a non-ceramic material (for example, a metal member). The surface 110 of the substrate 100 is flat in the present embodiment, but may be curved or tapered in portions.

The passivation film 200 is formed to protect the substrate 100 from plasma as described above. The passivation film 200 is formed to cover the entire surface 110 of the substrate 100. The passivation film 200 is composed of a material including lanthanum zirconium oxide as a main component. Lanthanum zirconium oxide described above is, for example, La₂Zr₂O₇. The ratio among the number of lanthanum (La) atoms, the number of zirconium (Zr) atoms and the number of oxygen (O) atoms in the passivation film 200 may be different from the ratio described above. The passivation film 200 of the present embodiment is formed by using an aerosol deposition method, but may be formed by another film-forming method.

As used herein, the “main component” refers to the compound contained in the greatest amount in the target object (in this case, passivation film 200). More specifically, the “main component” refers to the compound contained in the greatest amount in terms of volume ratio or mass ratio relative to other compounds in the object, as determined by quantitative or semi-quantitative analysis using X-ray diffraction (XRD) on the object.

The proportion of the main component (lanthanum zirconium oxide) in the passivation film 200 of the present embodiment is more than 50% by volume or by mass. The proportion may be more than 70%, more than 90%, or may be 100%.

The thickness of the passivation film 200 is appropriately adjusted depending on the duration for which resistance is required to be maintained and other factors. In the present embodiment, the passivation film 200 has a thickness of 15 μm or less.

The present inventors have used lanthanum zirconium oxide as a material for the passivation film 200 as in the present embodiment, and have been considering further improvement in the resistance of the material against plasma. As a result, it has been confirmed that there is a correlation between the indentation hardness of the passivation film 200 comprising lanthanum zirconium oxide as a main component and the resistance of the passivation film 200 against plasma.

The indentation hardness of the passivation film 200 was measured by performing a nanoindentation test for the surface 210 of the passivation film 200 formed on the substrate 100. The indentation hardness of the surface 210 was measured at several sites using a Berkovich indenter with an indentation depth fixed at 200 nm. The respective measurement sites were portions of the surface 210 free of scratches or pits. Provided that the surface 210 is polished to achieve a smooth finish before indentation hardness testing, measurements can be conducted with enhanced precision. The number of measurement sites was 10 or more, and the average of the indentation hardness values obtained from each site was determined as the indentation hardness of the passivation film 200. For specific testing methods, analytical methods, procedures for verifying testing device performance, and requirements for reference samples, methods specified in ISO14577 were employed.

The present inventors prepared multiple samples of the structural member 10 with varying film formation conditions for the passivation film 200, and measured indentation hardness and assessed resistance against plasma for each passivation film 200. To evaluate the resistance of the passivation film 200 against plasma, the surface 210 of each passivation film 200 was exposed to a plasma environment using an inductively coupling plasma reactive ion etching (ICP-RIE) system (not shown). The following two sets of conditions were employed when exposing the surface 210 to the plasma environment.

Under the first condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the passivation film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 30 minutes. The power output was set to 1,500 W for the ICP coil and 750 W for the bias. The plasma exposure test for the surface 210 of the passivation film 200, performed under the first conditions described above, is called the “First Standard Plasma Test” below. In the First Standard Plasma Test, by setting the bias output to 750 W as described above, the plasma is drawn toward the passivation film 200, and used for the etching of the passivation film 200.

Under the second condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the passivation film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 60 minutes. The power output was set to 1,500 W for the ICP coil, and the bias output was turned off (i.e., 0 W). The plasma exposure test for the surface 210 of the passivation film 200, performed under the second conditions described above, is called the “Second Standard Plasma Test” below. In the Second Standard Plasma Test, by turning off the bias output as described above, the plasma is not drawn toward the passivation film 200, and hardly used for the etching of the passivation film 200. The surface 210 of the passivation film 200 is simply exposed to non-directional plasma.

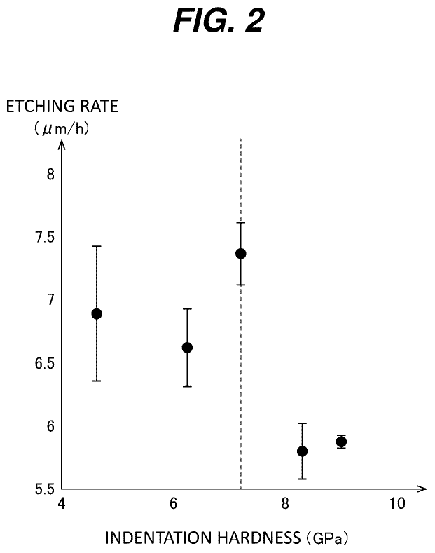

FIG. 2 shows the results of the First Standard Plasma Test described above conducted for each of the structural members 10. The horizontal axis of the graph in FIG. 2 represents the indentation hardness of the surface 210 of each sample, expressed in units of GPa. The measurement methods of the indentation hardness are as described above.

The vertical axis of the graph in FIG. 2 represents the etching rate in the First Standard Plasma Test, specifically the depth to which the passivation film 200 is etched per unit time, expressed in units of μm/h. The higher the resistance of the passivation film 200 against plasma, the smaller the etching rate of the passivation film 200. The etching rate may be used as an indicator of the resistance of the passivation film 200 against plasma.

FIG. 2 shows the etching rates, with error bars, obtained from the First Standard Plasma Test for five samples of the structural member 10 with varying indentation hardnesses of the passivation film 200.

As FIG. 2 clearly shows, the larger the indentation hardness value of the passivation film 200, the smaller the etching rate of the passivation film 200. For the passivation films 200 with an indentation hardness greater than 7.2 GPa, i.e., to the right of the dotted line in FIG. 2, the etching rate is sufficiently low, and sufficient resistance against plasma was verified.

If the indentation hardness of the passivation film 200 is 7.5 GPa or more, preferably 8.0 GPa or more, the etching rate is further reduced. Another experiment conducted by the present inventors have demonstrated that when the indentation hardness of the passivation film 200 is 14.0 GPa or more, the etching rate is further reduced compared to the above, and the resistance of the passivation film 200 against plasma can be further improved.

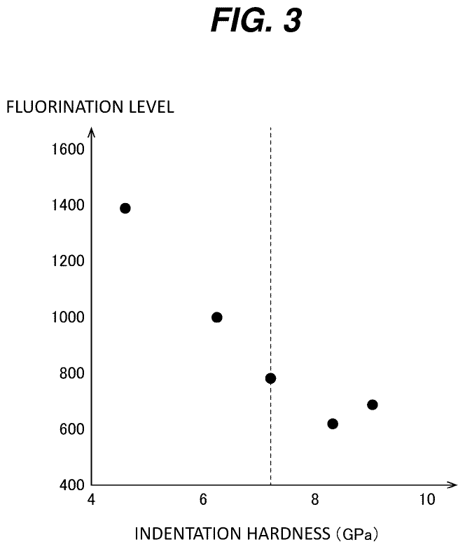

FIG. 3 shows the results of the Second Standard Plasma Test described above conducted for each of the structural members 10. The horizontal axis of the graph in FIG. 3 represents the indentation hardness of the surface 210 of each sample, expressed in units of GPa same as in FIG. 2. The samples prepared for the Second Standard Plasma Test were prepared by the same method as for the samples prepared for the First Standard Plasma Test. Therefore, the indentation hardness value of each sample shown in FIG. 3 is the same as the indentation hardness value of each sample shown in FIG. 2.

The vertical axis of the graph in FIG. 3 represents the fluorination level of the passivation film 200 after the Second Standard Plasma Test. The “fluorination level” is an indicator of how deep fluorine atoms, which are part of plasma, penetrate into the interior of the passivation film 200. Specific measurement methods of the fluorination level are as follows.

First, while sputtering the surface 210 of the passivation film 200 after the Second Standard Plasma Test using argon, the amount of fluorine atoms present on the surface 210 was continuously measured by X-ray photoelectron spectroscopy (XPS). The measurement was performed for 145 seconds. During the measurement, the proportion of the measured argon concentration in the overall composition (in %) was calculated at each time point, and the integrated value of these proportions was defined as the “fluorination level” of the sample. The higher the resistance of the passivation film 200 against plasma, the smaller the value of the fluorination level calculated as described above. Like the etching rate described above, the fluorination level may be used as an indicator of the resistance of the passivation film 200 against plasma.

As FIG. 3 clearly shows, the larger the indentation hardness value of the passivation film 200, the smaller the fluorination level of the passivation film 200. For the passivation film 200 with an indentation hardness greater than 7.2 GPa, i.e., to the right of the dotted line in FIG. 3, the fluorine level is sufficiently low, and sufficient resistance against plasma was verified.

If the indentation hardness of the passivation film 200 is 7.5 GPa or more, preferably 8.0 GPa or more, the fluorine level is further reduced. Another experiment conducted by the present inventors have demonstrated that when the indentation hardness of the passivation film 200 is 14.0 GPa or more, the fluorine level is further reduced compared to the above, and the resistance of the passivation film 200 against plasma can be further improved.

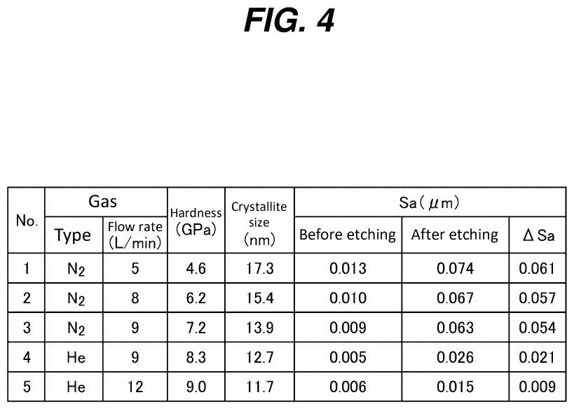

The method and other conditions for producing the samples used in the above measurement will be described with reference to FIG. 4. In FIG. 4, Sample No. 1 was prepared under conditions where the indentation hardness of the passivation film 200 was 4.6 GPa. Sample No. 2 was prepared under conditions where the indentation hardness of the passivation film 200 was 6.2 GPa; Sample No. 3 was prepared under conditions where the indentation hardness of the passivation film 200 was 7.2 GPa: Sample No. 4 was prepared under conditions where the indentation hardness of the passivation film 200 was 8.3 GPa; and Sample No. 5 was prepared under conditions where the indentation hardness of the passivation film 200 was 9.0 GPa.

All of the passivation film 200 samples No. 1 to 5 were formed by using an aerosol deposition method. As is well known, in the aerosol deposition method, fine particles constituting the passivation film 200 are dispersed in a gas to form an aerosol, which is then sprayed from a nozzle toward the surface 110 to collide with it. At the surface 110, fine particles are deformed or fractured upon collision, bonding and depositing progressively to form the passivation film 200. FIG. 4 shows the type of the gas described above used in the film-forming of the samples and the flow rate in spraying the gas from the nozzle.

A La₂Zr₂O₇ powder was used as the “fine particles” described above. The powder had an average particle size of 2.3 μm and a median diameter of 2.1 μm.

As shown in FIG. 4, Samples No. 1 to 5 differ from one another in terms of the film-forming conditions for passivation film 200 (specifically, gas type and flow rate), resulting in distinct indentation hardnesses of the passivation film 200.

Samples No. 1 to 5 were each prepared in pairs. The First Standard Plasma Test was conducted on one of each pair, yielding the results shown in FIG. 2. The Second Standard Plasma Test was conducted on the other, yielding the results shown in FIG. 3.

The present inventors measured the arithmetic mean height (Sa) of the surface 210 for Samples No. 1 to 5 before and after conducting the First Standard Plasma Test. In the “Before etching” column of the table in FIG. 4, the arithmetic mean height of the surface 210, measured prior to the First Standard Plasma Test, is shown in μm. In the “After etching” column, the arithmetic mean height of the surface 210, measured after the First Standard Plasma Test, is shown in μm. In the “ΔSa” column, the difference in the above two arithmetic mean heights is shown. Namely, the variation in the arithmetic mean height of the surface 210 after conducting the First Standard Plasma Test is shown in μm. The method specified in ISO25178 was used as the measurement method of the arithmetic mean height.

For Samples No. 1 to 3, namely, samples with an indentation hardness of the passivation film 200 of 7.2 GPa or less, the arithmetic mean height of the surface 210 of the passivation film 200 after conducting the First Standard Plasma Test exceeds 0.05 μm. On the other hand, for Samples No. 4 and 5, namely, samples with an indentation hardness of the passivation film 200 of more than 7.2 GP, the arithmetic mean height of the surface 210 of the passivation film 200 after conducting the First Standard Plasma Test is lower than 0.05 μm.

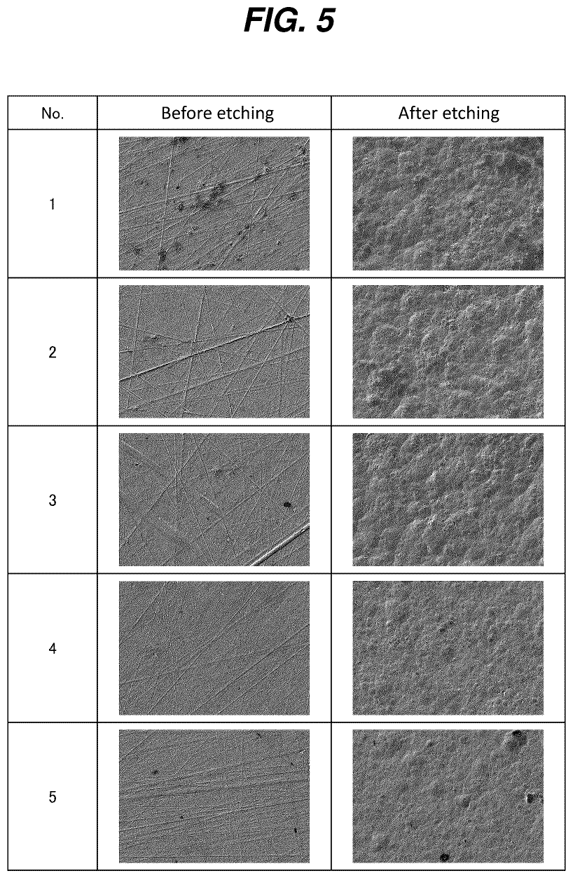

The present inventors observed the surface 210 of Samples No. 1 to 5 before and after conducting the First Standard Plasma Test using a scanning electron microscope (SEM). FIG. 5 shows images obtained from the observation. The images are what are called “secondary electron images,” which were obtained at an accelerated voltage of 3 kV. The magnification is 5000×. Images from the observation before the First Standard Plasma Test are shown in the “Before etching” column in FIG. 5. Images from the observation after the First Standard Plasma Test are shown in the “After etching” column in FIG. 5.

The present inventors also measured the porosity of the passivation film 200. The “porosity” as used herein refers to the proportion of the cross-sectional area occupied by pores, expressed as a percentage, in cross-sections of the passivation film 200 cut in a plane perpendicular to the surface 210.

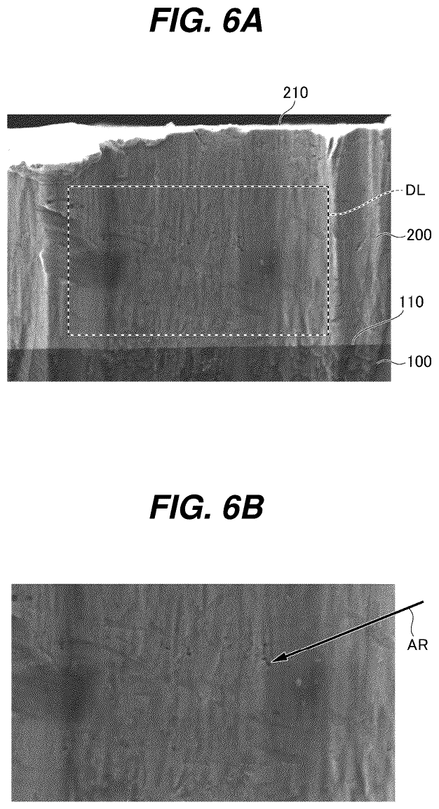

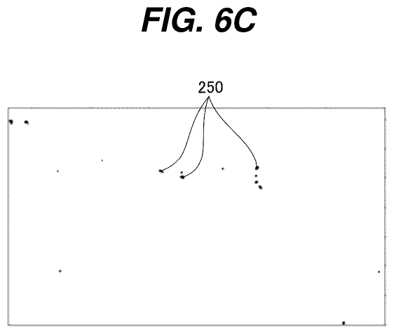

The method for measuring the porosity is as follows. First, the cross-sections described above are observed using a scanning electron microscope (SEM), and secondary electron images were obtained. The accelerated voltage was 3 kV and the magnification was 30,000×. FIG. 6A shows an example of images obtained by the procedure described above. The subject of the measurement is Sample No. 4 in the table in FIG. 4.

Next, by analyzing the images obtained as described above, the porosity of the passivation film 200 was calculated. Image analysis was performed using the OpenCV library in Python. The images were cropped to contain only the cross-section of the passivation film 200. Specifically, regions outside the dotted line DL in FIG. 6A were cropped.

FIG. 6B shows the image after the cropping described above. The entire image consists of the cross-section of the passivation film 200. In the image of FIG. 6B, dark spots, one of which is indicated by arrow AR, are the cross-sections of pores contained within the passivation film 200.

After cropping, the image of FIG. 6B was binarized to render the cross-sections of pores as black and other regions as white. The binarization was performed by applying the “Variable Threshold Binarization method” described in The Journal of the Institute of Image Electronics Engineers of Japan, 36(3), pp. 204-209, 2007. Subsequently, noise pixels were removed by dilation or other measures, yielding the binary image shown in FIG. 6C. In FIG. 6C, the black spots labeled 250 represent the cross-sections of pores contained within the passivation film 200.

The ratio of black pixels to total pixels in the image of FIG. 6C was determined as the porosity of the passivation film 200. In the example of FIG. 6C, the total number of pixels of the image was 947,200, with 981 black pixels. Therefore, the porosity was determined as approximately 0.10%. The present inventors have demonstrated that when the indentation hardness of the passivation film 200 is more than 7.2 GPa and the porosity of the passivation film 200 is 0.15% or less, the resistance of the passivation film 200 against plasma can be further improved.

The present inventors have also demonstrated that by forming the passivation film 200 so that the average crystallite size is 50 nm or less, the resistance of the passivation film 200 against plasma can be further improved. The “average crystallite size” refers to the average diameter of the circles obtained by performing circular approximation on at least 15 crystallites present on the surface 210 of the passivation film 200. To calculate the average crystallite size of the passivation film 200, the surface 210 of the passivation film 200 is imaged using a Transmission Electron Microscope (TEM), and the average crystallite size can be calculated based on the acquired images. In this case, the magnification should preferably be 400,000× or higher.

The table in FIG. 4 shows the average crystallite sizes of the passivation films 200 of Samples No. 1 to 5 calculated as described above. For each sample, the average crystallite size of the passivation film 200 was determined to be 50 nm or less. By forming the passivation film 200 to have an average crystallite size of preferably 30 nm or less, and more preferably 15 nm or less, the resistance of the passivation film 200 can be further improved.

The more it is attempted to form a passivation film 200 with higher indentation hardness, the more easily the densification due to fracture and deformation proceeds during film formation. Thus, as the indentation hardness of the passivation film 200 increases, the average crystallite size of the passivation film 200 tends to decrease.

In semiconductor manufacturing apparatus, wet etching is sometimes performed on a substrate using an acidic aqueous solution such as hydrochloric acid for cleaning. During wet etching, both the substrate and the surface of the passivation film 200 are exposed to the acidic aqueous solution, and thus the surface shape may change by the acidic aqueous solution. Such changes in the surface shape are undesirable for maintaining the function of the passivation film 200 over an extended period. Therefore, the passivation film 200 must have resistance against corrosion from acidic aqueous solution as well as resistance against plasma.

The experiments conducted by the present inventors have demonstrated that by reducing the average crystallite size of the passivation film 200, resistance against plasma increases, while resistance against corrosion by acidic aqueous solutions decreases, as mentioned above.

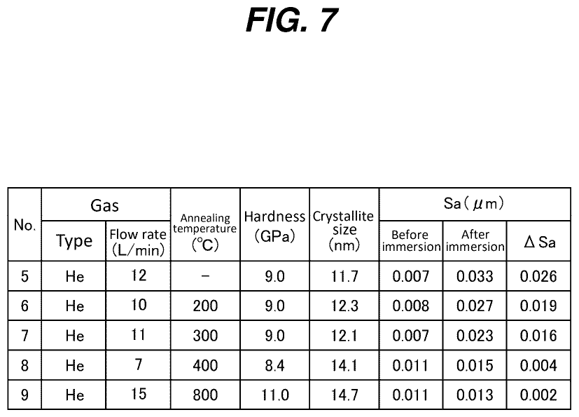

To demonstrate the relationship between the average crystallite size of the passivation film 200 and its resistance against acidic aqueous solution, the present inventors conducted the additional experiments, described below, using an aqueous hydrochloric acid solution, which is one of the acidic aqueous solutions used for wet etching. FIG. 7 shows parameters including production conditions for each of five samples prepared for the experiment.

Samples No. 5 to 9, shown in FIG. 7, are prepared by forming passivation film 200 on the surface 110 of the substrate 100 by using an aerosol deposition method, in the same manner as the samples in FIG. 4. La₂Zr₂O₇ powder was used as fine particles sprayed from the nozzle during film forming. The powder had an average particle size of 2.3 μm and a median diameter of 2.1 μm. Sample No. 5, designated as such in FIG. 7, is a sample produced in the same manner as Sample No. 5 previously described in connection with FIG. 4.

FIG. 7 shows, as in FIG. 4, the type of the gas used in the film forming of the samples and the flow rate in spraying the gas from the nozzle, respectively.

After forming the passivation film 200, Samples No. 6 to 9 were heated (annealed) before measuring the indentation hardness and the crystallite size. On the other hand, annealing was not performed for Sample No. 5.

In annealing, each sample was annealed until the temperature of the passivation film 200 reached the respective temperatures shown in the “Annealing temperature” column in FIG. 7 at a temperature-increasing rate of 50° C./hour. After completing the temperature increase, the temperature of the passivation film 200 was maintained at that temperature for 240 minutes and then the passivation film 200 was cooled at a cooling rate of 50° C./hour.

For Samples No. 6 to 9, after annealing and their temperature had returned to room temperature, the indentation hardness and the crystallite size of the passivation film 200 were measured. For Sample No. 5, the indentation hardness and the crystallite size of the passivation film 200 were measured after film formation without annealing. The measured values of the indentation hardness and the crystallite size of each sample are shown in the column of “Hardness” and “Crystallite size” in FIG. 7.

As shown in FIG. 7, a tendency was observed that the higher the temperature of the passivation film 200 in annealing, the more its indentation hardness increased and the larger the average crystallite size became. By selecting conditions of annealing appropriately, the indentation hardness and the crystallite size of the passivation film 200 can be maintained within the predetermined range.

The present inventors observed how the surface roughness of the passivation film 200 changed by immersing Samples No. 5 to 9 in an aqueous hydrochloric solution after the measurement of the indentation hardness and the crystallite size of the passivation film 200. In the “Before immersion” column in FIG. 7, the arithmetic mean height (Sa) of the surface 210 of the passivation film 200, measured before immersion in the aqueous hydrochloric solution, is shown in μm. In the “After immersion” column, the arithmetic mean height (Sa) of the surface 210, measured after immersion in the aqueous hydrochloric solution for 60 minutes, is shown in μm. In “ΔSa” column, the difference between the two arithmetic mean heights is shown. Namely, the variation in the arithmetic mean height of the surface 210 after immersion in the aqueous hydrochloric solution is shown in μm. The hydrochloric acid concentration of the aqueous hydrochloric acid solution was 6.2% and the temperature of the aqueous hydrochloric acid solution was 25° C. The method specified in ISO25178 was used as the measurement method of the arithmetic mean height.

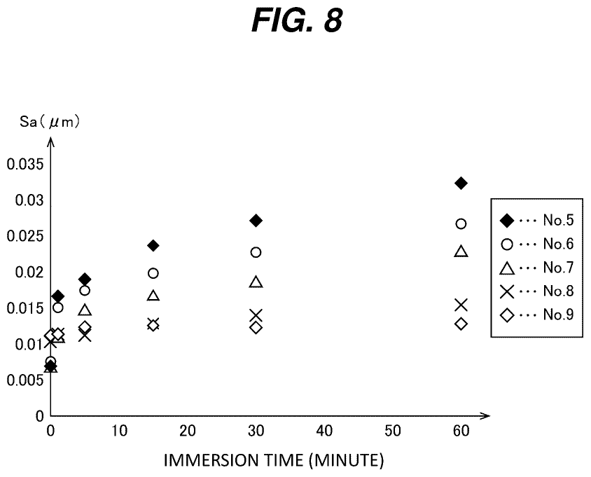

The arithmetic mean height of the surface 210 was measured not only at the time point of 60 minutes after the start of immersion in the aqueous hydrochloric acid solution but also at time points of 1, 5, 15, and 30 minutes after the start of immersion in the aqueous hydrochloric acid solution. FIG. 8 shows the values of arithmetic mean height of the surface 210 of Samples 5 to 9, measured at the time points described above. The “Immersion time” on the horizontal axis of FIG. 8 indicates the time in minutes from the start of immersion of the passivation film 200 in the aqueous hydrochloric acid solution.

As shown in FIGS. 7 and 8, a tendency was observed that the higher the annealing temperature applied to each sample previously, the larger the crystallite size of the passivation film 200 became and the smaller the shape change (ΔS) of the surface 210 became after immersion in the aqueous hydrochloric acid solution. In other words, it was confirmed that the larger the crystallite size of the passivation film 200 achieved by annealing, the greater the resistance of the passivation film 200 against hydrochloric acid became. It was also confirmed that to ensure sufficient resistance against wet etching conducted in semiconductor manufacturing apparatus, the crystallite size of the passivation film 200 needs to be set at 12 nm or more, as in the samples other than Sample No. 5. Furthermore, when the present inventors additionally fabricated multiple samples and conducted the same experiments described above, it was confirmed that the smaller the crystallite size of the passivation film 200, the greater the change in surface roughness resulting from immersion in the aqueous hydrochloric acid solution.

As described above, to ensure sufficient resistance of the passivation film 200 against plasma, it is preferable to set the crystallite size of the passivation film 200 to 50 nm or less. Therefore, it is preferable to maintain the crystallite size of the passivation film 200 within a range of 12 nm or more and 50 nm or less. It is preferable that the annealing temperature and the temperature increase rate are selected such that the crystallite size of the passivation film 200 is within the aforementioned range and the passivation film 200 is less likely to be damaged by thermal stress. When the passivation film 200 has a thickness of 15 μm as in the present embodiment, it is preferable to set the annealing temperature, for example, within a range of 200° C. to 300° C.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a substrate, and
a passivation film covering a surface of the substrate,
wherein the passivation film comprises lanthanum zirconium oxide as a main component, and
the passivation film has an indentation hardness of more than 7.2 GPa.

2. The structural member according to claim 1, wherein the passivation film is formed by using an aerosol deposition method.

3. The structural member according to claim 1, wherein the lanthanum zirconium oxide is La₂Zr₂O₇.

4. The structural member according to claim 1, wherein the passivation film has an indentation hardness of 7.5 GPa or more.

5. The structural member according to claim 1, wherein the passivation film has an indentation hardness of 8.0 GPa or more.

6. The structural member according to claim 1, wherein the passivation film has an indentation hardness of 14.0 GPa or more.

7. The structural member according to claim 1, wherein the passivation film has an average crystallite size of 50 nm or less.

8. The structural member according to claim 7, wherein the passivation film has an average crystallite size of 12 nm or more.

9. The structural member according to claim 1, wherein the passivation film has a thickness of 15 μm or less.

10. The structural member according to claim 1, wherein an arithmetic mean height of a surface of the passivation film after conducting First Standard Plasma Test is smaller than 0.05 μm.

11. The structural member according to claim 1, wherein the passivation film has a porosity of 0.15% or less.

12. The structural member according to claim 1, which is configured as a member for a semiconductor manufacturing apparatus.
